(19) United States
(12) Patent Application Publication
(10) Pub. No.: US 2002/0022383 A1
(43) Pub. Date: Feb. 21, 2002

(54) Compression connector

(76) Inventors: Tsuyoshi Sakata, Tokyo (JP); Takashi Nagawatari, Tokyo (JP)

Correspondence Address: KANESAKA & TAKEUCHI, 1423 Powhatan Street, Alexandria, VA, 22314, US

(21) Appl. No.: 09/908,545

(22) Filed: Jul. 20, 2001

(30) Foreign Application Priority Data
Aug. 15, 2000 (JP) 2000-246427

(51) Int. Cl. H05K 1/00

(52) U.S. Cl. 439/66

(57) ABSTRACT

A compression connector (10) comprises an insulation sheet (11) having a plurality of retention holes, a plurality of elastic contacts (12) provided in the retention holes to make elastic contact with a pair of boards (20) and (30) and a printed line (13) provided on at least one face of the insulation sheet (11) to connect the elastic contacts (12).

### BACKGROUND OF THE INVENTION

1. Field of the Invention

The present invention relates to compression connectors having an insulation sheet with a plurality of conductive elastomer contacts for making compression contact with the connection lands of a mating board.

2. Description of the Related Art

Such compression connectors as described above are well known. For example, as shown in FIG. 4, a compression connector 50 has an insulation sheet 51 and a plurality of contacts 52 provided in place on the sheet. The contacts 52 are made of a conductive elastomer such that truncated conic sections project from either face of the insulation sheet 51 and are compressible under pressure in the thicknesswise direction of the insulation sheet 51. Such a compression connector is widely used as an intermediate connector for connecting a pair of boards 60 and 70.

Electronic circuits are provided on the boards 60 and 70, respectively, to connect electronic components (not shown). A plurality of connection lands 61 or 71 are provided on the lower or upper face of each of the boards 60 and 70 at positions corresponding to the elastic contacts 52 of the compression connector 50. Some of the connection lands 61 or 71 are connected by inserting the ends of a cable 63 or 73 into through-holes 62 or 72 in the board 60 or 70. Alternatively, as shown in FIG. 5, they are connected by a printed circuit line 64 or 74.

In use, the elastic contacts 52 of the compression connector 50 are compressed between the connection lands 61 and 71 of the boards 60 and 70 to electrically connect the boards 60 and 70.

However, the above compression connector has some disadvantages.

Usually, each board has an extremely complex circuit and closely mounted electronic components thereon so that when the board circuit is changed, the resoldering can adhere to adjacent circuit lines to make short circuit, causing malfunction of the entire circuit. If a plurality of crossed lines are provided in layers, the device thickness is increased by that much. The electronic components are mounted too densely to add any component or circuit line.

### SUMMARY OF THE INVENTION

Accordingly, it is an object of the invention to provide a compression connector that permits addition or change of circuit and/or components of equipment without changing the board on which the circuit and/or components are mounted.

According to the invention there is provided a compression connector which comprises an insulation sheet having a plurality of retention means; a plurality of elastic contacts made of a conductive elastomer so as be compressible in a thicknesswise direction of the insulation sheet and provided in the retention means so as to project from the insulation sheet to make elastic contact with corresponding connection sections of a pair of boards; and at least one printed line provided on at least one face of the insulation sheet to connect the elastic contacts.

The above compression or intermediate connector is sufficiently simple to make change or replaced with another to make change or addition to the electrical circuit of equipment without making any change to the boards on which complex circuits and/or electronic components are mounted.

At least one insulation film may be provided on one of the elastic contacts that does not need to make contact with one of the boards. Where the connection between elastic contacts of the intermediate connector is complex, at least one inner layer printed line may be provided in the insulation sheet to connect at least some of the elastic contacts. The retention members are retention holes that go through the insulation sheet and are provided on inside with a conductive member to make connection with the inner layer printed line.

### BRIEF DESCRIPTION OF THE DRAWINGS

FIG. 1 is a perspective view of a pair of boards and a compression connector according to an embodiment of the invention;

FIG. 2 is a sectional view of the compression connector;

FIG. 3 is a sectional view of a compression connector according to another embodiment of the invention;

FIG. 4 is a perspective view of a conventional compression connector; and

FIG. 5 is a perspective view of another conventional compression connector.

### DESCRIPTION OF THE PREFERRED EMBODIMENTS

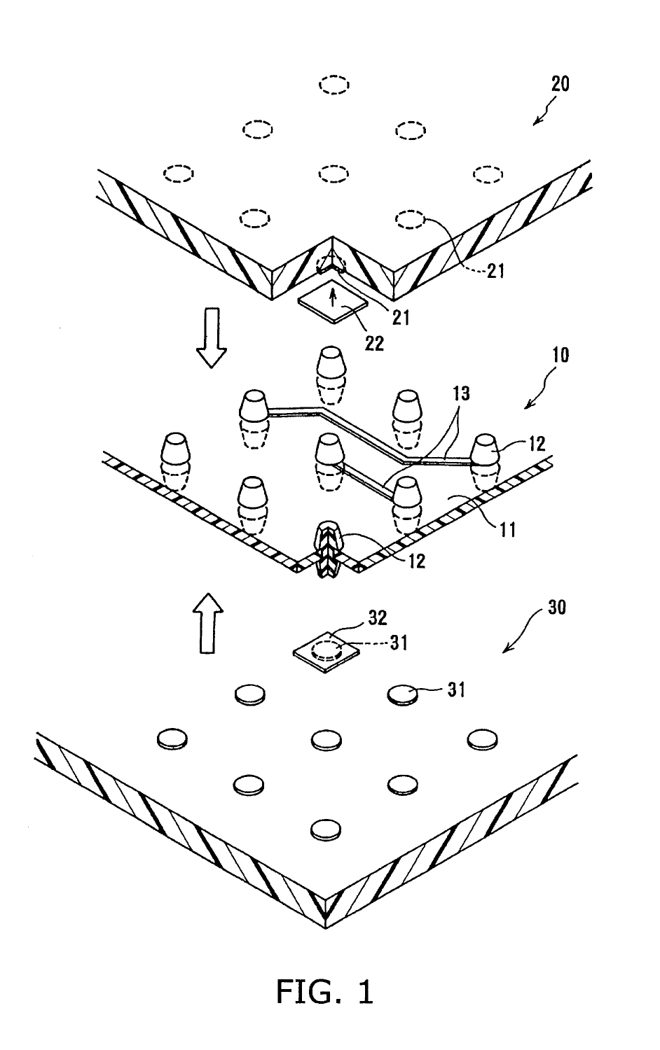

Embodiments of the invention will now be described with reference to FIGS. 1-3.

In FIG. 1, a compression connector 10 is used as an intermediate connector for connecting a pair of boards 20 and 30. Although not shown, the boards 20 and 30 have electrical circuits and electronic components closely mounted on one or both faces of each board. Such electrical circuits have connection lands 21 and 31, respectively. Usually, these connection lands 21 and 31 are provided by printed circuit technology at corresponding positions on the face on the connection side. In the figure, only the connection lands 21 and 31 are shown. An insulation film 22 or 32 is provided on the connection land that requires no connection to the corresponding connection lands 32 or 22 through the compression connector 10.

The compression connector 10 comprises an insulation sheet 11 that is thinner and more flexible than the boards 20 and 30 and a plurality of elastic contacts 12. A plurality of retention holes are provided in the insulation sheet 11 at positions corresponding to connection lands 21 and 31 of the boards 20 and 30, respectively, to support the elastic contacts 12. Each elastic contact 12 has a pair of truncated conic sections and a neck section between them that is fitted in a retention hole of the insulation sheet 11. Usually, the elastic contacts 12 are molded from a conductive elastomer so as to have electrical conductivity and flexibility so that they are compressible under pressure in the thicknesswise direction of the insulation sheet. The conductive elastomer is well known and the detailed description will be omitted.

A plurality of printed lines 13 are provided on the insulation sheet 11 to connect elastic contacts 11. They are provided as circuit additions or changes prior to installation of the elastic contacts 11. Where further addition or change is desired, the compression connector 10 is replaced by another having an insulation sheet that has a desirable printed circuit thereon.

When the compression connector 10 is placed and incorporated between the boards 20 and 30, the elastic contacts 12 make elastic contact with the connection lands 21 and 31 under satisfactory pressures to electrically connect the boards 20 and 30. Thus, it is possible to change the electrical circuit of the equipment without changing the boards 20 and 30.

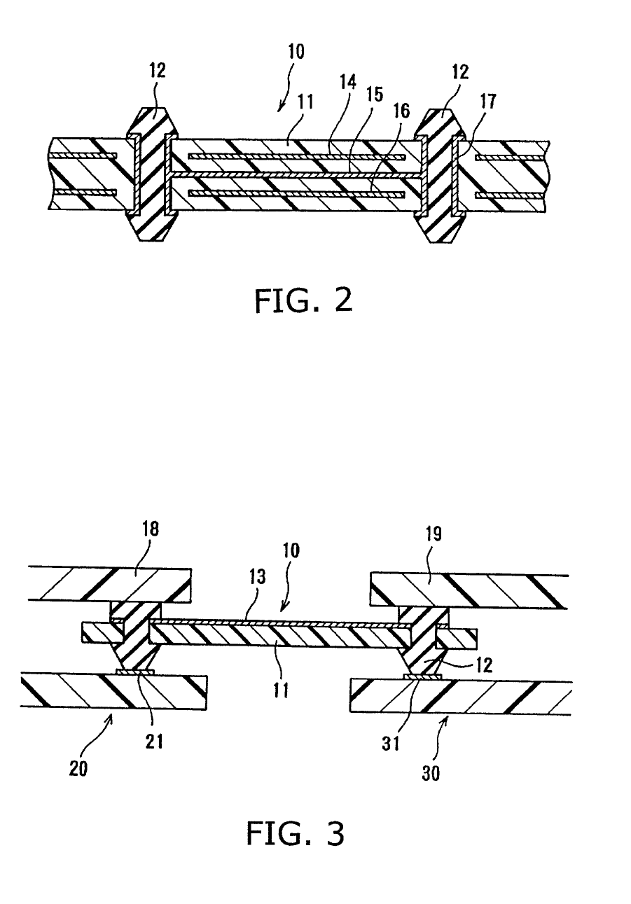

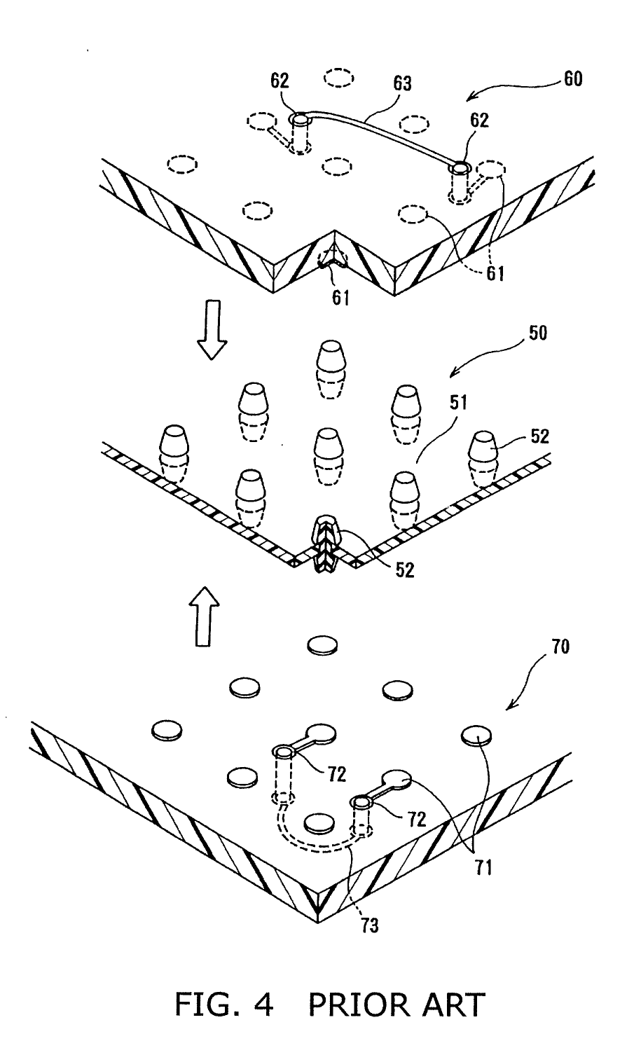

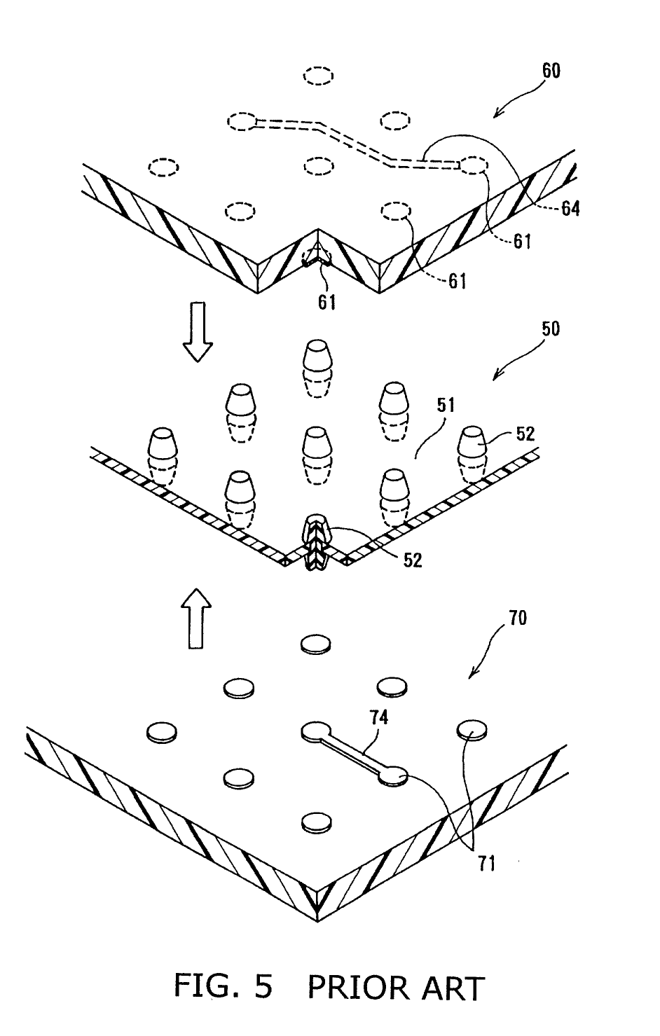

As shown in FIG. 2, where the electrical circuit that is to be changed by the compression connector is complex, a plurality of inner layer printed lines 14, 15, and 16 are provided in the insulative sheet. The inner layer printed lines may be made on a plurality of layers along with such printed lines 13 as shown in FIG. 1, wherein they are provided on the upper face of the insulative sheet. The inner layer printed lines make 3-D wiring and complex line arrangement possible. A conductive member 17 is provided on the inner surface of each retention hole to assure contact with the elastic contact 12.

In FIG. 3, the compression connector 10 connects the boards 20 and 30 that are provided in a plane. The compression connector 10 comprises an insulative sheet 11 and a plurality of conductive elastomer contacts 12 that are attached to the insulative sheet 12 and connected by a printed line 13. A pair of pressure plates 18 and 19 are provided above the compression connector 10 to press down the elastic contacts 12 onto the boards 20 and 30. Consequently, the connection lands 21 and 31 of the boards 20 and 30, respectively, are connected via the elastic contacts 12 and the printed line 13 to permit addition to or change of the electrical circuit of the equipment that has the boards 20 and 30.

As has been described above, according to the invention, the elastic contacts of a compression connector are connected by the printed lines so that it is easy to change the electrical circuit of equipment by merely making change to or replacing the compression connector without making any change to the board on which the complex circuit and electronic components mounted densely. Since the compression connector has a simple contact arrangement, the printed lines are readily made on and between layers and very versatile.

1. A compression connector comprising:
an insulation sheet having a plurality of retention means;
a plurality of elastic contacts made of a conductive elastomer so as be compressible in a thicknesswise direction of said insulation sheet and provided in said retention means so as to project from said insulation sheet to make elastic contact with corresponding connection sections of a pair of boards;
at least one printed line provided on at least one face of said insulation sheet to connect said elastic contacts.

2. The compression connector according to claim 1, which further comprises at least one insulation film provided on one of said elastic contacts that does not need to make contact with one of said boards.

3. The compression connector according to claim 1, which further comprises at least one inner layer printed line provided in said insulation sheet to connect at least some of said elastic contacts.

4. The compression connector according to claim 3, wherein said retention means are retention holes that go through said insulation sheet and are provided on inside with a conductive member to make connection with said inner layer printed line.
